(19) United States
(12) Patent Application Publication
(10) Pub. No.: US 2005/0092504 A1
(43) Pub. Date: May 5, 2005

(54) Personal electromagnetic security unit and method for electromagnetically shielding portable electronic communication and data devices and the like

(76) Inventors: Lacy M. Walthall, Wake Forest, NC (US); Robert C. Boyd, Richmond, VA (US); Wayne B. Legrande, Chesapeake, VA (US)

Correspondence Address: JACOBSON HOLMAN PLLC, 400 SEVENTH STREET N.W., SUITE 600, WASHINGTON, DC, 20004, US

(21) Appl. No.: 10/978,348

(22) Filed: Nov. 2, 2004

Related U.S. Application Data
(60) Provisional application No. 60/516,322, filed on Nov. 3, 2003.

(51) Int. Cl. H05K 9/00

(52) U.S. Cl. 174/35 MS

(57) ABSTRACT

A personal electromagnetic security unit for shielding portable electronic communication and data devices such as cell phones and computers. The shielding unit includes a coated liner construction in which a high-attenuation metallized fabric is coated with a second attenuating material to enhance the electromagnetic absorption or reflection characteristics of the unit. This two-part conductive layer forms the inner liner of the shielding unit, with the coated side being protected by the unit's exterior material and preferably an intervening layer of padding.

This application is entitled to and hereby claims the priority of co-pending U.S. Provisional application Ser. No. 60/516,322 filed Nov. 3, 2003.

### BACKGROUND OF THE INVENTION

1. Field of the Invention

The present invention is directed to units for shielding electronic equipment using electromagnetic radiation absorptive or reflective coating compositions and the like.

2. Brief Description of the Prior Art

Portable electronic communication and data devices such as laptop computers, personal digital assistants and cell phones are often subjected to wireless signals which are not wanted by the user, whether due to the timing of the signal receipt or the source. For example, an unauthorized third party may attempt to wirelessly access a remotely located PDA, or the user may require privacy without the interruption of the mobile device due to an incoming data signal, such as a phone call.

Known shielding units for portable devices exhibit a single conductive fabric layer in conjunction with an exterior material layer, but these units are only partially effective in shielding communication and data device operation. In addition to material limitations, shielding breaches often result from the unreliable mechanisms by which the known units are closed, namely loose, poorly sealing flaps which significantly limit shielding effectiveness.

Accordingly, a need exists for a shielding unit that is able to truly shield any of a variety of portable electronic devices from unwanted incoming signals through signal attenuation, in a manner that is easy and convenient to use.

### SUMMARY OF THE INVENTION

In view of the foregoing, one object of the present invention is to provide a shielding unit made with a metallized fabric provided with an attenuating barrier coating composition having an attenuating characteristic with at least one of electromagnetic radiation reflective and absorptive properties.

Another object of the present invention is to provide a two-part barrier layer within a shielding unit in which an electromagnetically attenuating coating composition is applied to an electromagnetically attenuating fabric and protected in use by the uncoated side of the fabric on one side and padding material adjacent the unit's exterior material on the other side.

A further object of the present invention is to provide a shielding unit that provides long-term shielding effectiveness while being attractive, durable and easy to use.

A still further object of the present invention is to provide a shielding unit having an overlapping flap closure with snap-in clasp to reliably obtain proper tension across the conductive lip of the unit and thereby achieve a complete electromagnetic conductive seal.

Yet another object of the present invention is to provide a shielding unit that is not complex in structure and which can be manufactured at reasonable cost but yet efficiently protect a variety of electronic devices from unwanted signal exposure.

In accordance with these and other objects, the present invention is directed to a personal electromagnetic security unit for shielding portable electronic communication and data devices such as cell phones and computers. The shielding unit includes a high attenuation fabric having a second attenuating material coated across at least one side thereof to create a more effective electromagnetic shielding barrier that absorbs and/or reflects incoming electromagnetic energy. This two-part barrier layer forms the inner liner of the shielding unit, with the coated side of the fabric facing the unit's exterior material. A padding material is preferably interposed between the coated side of the inner liner and the exterior material to protect the coating layer. The unit closes securely with an overlapping flap and snapping clasp to achieve a complete electromagnetic seal.

These together with other objects and advantages which will become subsequently apparent reside in the details of construction and operation as more fully hereinafter described and claimed, reference being had to the accompanying drawings forming a part hereof, wherein like numerals refer to like parts throughout.

### BRIEF DESCRIPTION OF THE DRAWINGS

FIG. 1 shows a personal electromagnetic security (PEMS) unit for a personal digital assistant, in accordance with the present invention;

FIG. 2 shows a horizontal PEMS unit for a cell phone, in accordance with the present invention;

FIG. 3 shows a vertical PEMS unit for a cell phone, in accordance with the present invention;

FIG. 4 is a cross-sectional view of the vertical PEMS unit taken along line 4-4 of FIG. 3; and

FIG. 5 is a cross-sectional view of the preferred two-part barrier layer construction taken along line 5-5 of FIG. 4.

### DESCRIPTION OF THE PREFERRED EMBODIMENTS

In describing a preferred embodiment of the invention illustrated in the drawings, specific terminology will be resorted to for the sake of clarity. However, the invention is not intended to be limited to the specific terms so selected, and it is to be understood that each specific term includes all technical equivalents which operate in a similar manner to accomplish a similar purpose. In addition, although several preferred compositions for the coated liner of the shielding unit of the present invention are disclosed, it is to be understood that the exact compositions are given by way of illustration only. It is not intended that the invention be limited in its scope to the exact construction or the particular compositions set forth in the following description.

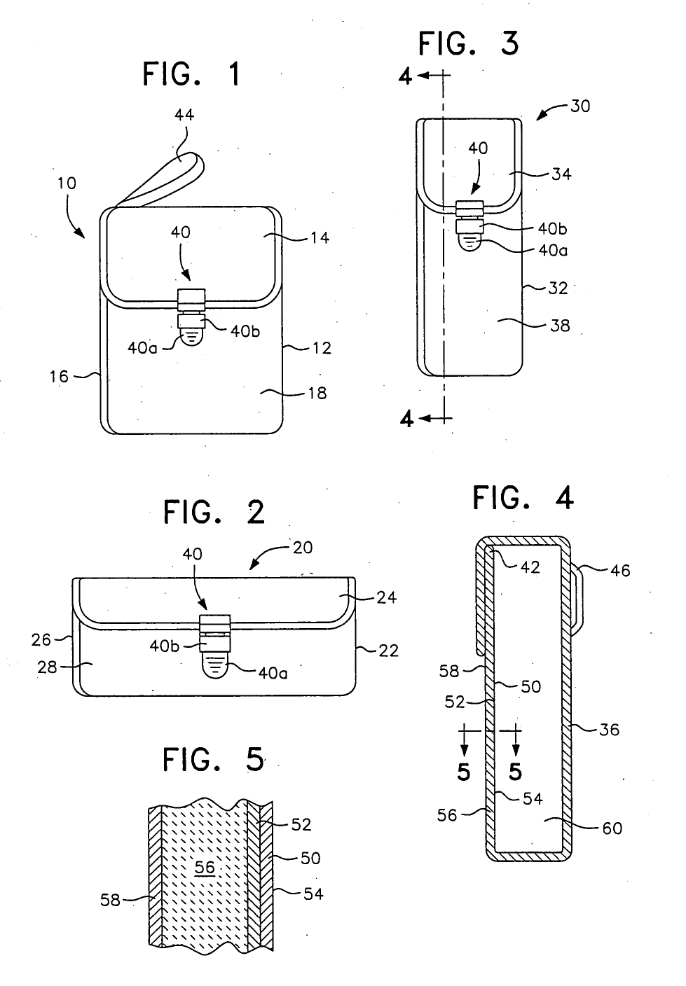

As representatively illustrated in FIG. 1, the present invention is directed to a personal electromagnetic security (PEMS) unit, generally designated by the reference numeral 10, for electromagnetically shielding portable electronic communication and data devices and the like. The PEMS unit may be constructed with different shapes and in different configurations to accommodate a range of different electronic devices. The PEMS unit 10 is suited to enclose a personal data assistant (PDA), while the PEMS units shown in FIGS. 2 and 3, generally designated by the reference numerals 20 and 30, respectively, are designed for cell phone shielding. A laptop PEMS unit (not shown) is also available, as are other designs for particular types of equipment to be shielded from electromagnetic signals.

In each of the embodiments shown in FIGS. 1-3, the PEMS unit includes a body 12, 22, 32 into which the intended electronic device is inserted. A overlapping flap 14, 24, 34 is integrally formed with and extends from a rear body panel 16, 26, 36 of said body to fit down over the front panel 18, 28, 38 of the body.

The flap is secured to the front panel 18, 28, 38 by a snap-in clasp 40 that precisely creates the proper tension across the interior lip 42 of the unit, shown in FIG. 4, thereby achieving a complete electromagnetic seal. The clasp 40 is preferably made of plastic and has a construction commonly known and used in various backpacks, luggage, duffle bags, etc., in which a male element 40a affixed to the flap 14, 24, 34 snaps into a corresponding female element 40b attached to the front panel 18, 28, 38. Alternatively, the male element could be attached to the flap and the female element to the front panel. Other known clasp-type constructions including magnetic catches may also be used.

Each PEMS unit will preferably include a structure enabling the unit to be easily carried or attached to a desired object. For example, the PDA PEMS unit 10 may include a handle or finger loop 44, and/or any suitable structure to which a necklace may be affixed. The cell phone PEMS units 20, 30 are preferably provided with a belt loop 46, shown in FIG. 4, or clips (not shown), or other elements as would be known in the art relating to portable devices, including but not limited to sunglasses, pagers, fanny packs, etc. The laptop computer PEMS unit (not shown) is preferably provided with a hand-carry handle.

As illustrated in FIGS. 4 and 5, the body and the flap have a layered construction, with the inner liner being made using a high attenuation, metallized fabric 50 as a substrate. This fabric is commercially available and is representively embodied by any of the light-weight, nickel/copper polyester fabrics that are known on the market or any other metallized fabric type, including copper-coated fabrics, silver-coated fabrics, etc. A second layer formed by an attenuating coating layer 52 is applied across one side of the substrate fabric 50, such as by spray-coating or other suitable method, to create a more effective electromagnetic shielding barrier than is possible with single-layer, non-coated constructions. In use of the resulting two-part barrier layer 50, 52, which constitutes the inner liner element of the body and the flap, the coating layer 52 is preferably protected between the non-coated side 54 of the liner with padding material 56 that is adjacent the unit's durable exterior material 58.

The coating layer 52 is highly durable and sufficiently flexible to allow folding over of the underlying metallized fabric without cracking of the coating in thicknesses necessary to achieve the high level of attenuation desired for the present invention. According to a preferred embodiment of the two-part barrier layer, the coating layer 52 has a thickness of between about 0.001 and about 0.01 inches, and preferably between 0.002 and 0.006 inches. Thicknesses above 0.01 inches are possible, but care must be taken to avoid cracking and thus compromise of the shielding barrier.

In constructing the two-part barrier layer 50, 52, the barrier coating 52 may be one of several coating compositions which are suitable for use with the present shielding unit; a full disclosure of such coating alternatives is provided in a commonly owned and co-pending international application, PCT/02/07039, filed Mar. 8, 2002, and published as WO 03/078531, which is incorporated by reference as if fully set forth herein.

In the present invention, according to a preferred embodiment, the coating material composition is representatively formulated as follows:

| Composition | Weight in |
|---|---|
| Component | parts per 100/Wt. |
| Acrylic Resin #1 | 31.0 |
| XHNBR Latex #1 | 11.0 |
| Water | 12.5 |
| Ethylene Glycol Monobutly Ether | 5.0 |
| Defoamer #1 | 1.0 |
| Surfactant | 1.0 |
| Conductive Spheres | 32.0 |
| Graphite | 5.5 |

The foregoing components are identified in detail in WO 03/078531.

In formulating the above composition, the Acrylic Resin #1 was placed in a suitable vessel for mixing and slow speed agitation was begun. The XHNBR Latex #1 was added at a slow rate and allowed to mix with the Acrylic Resin for 5 minutes. Water and glycol ether were premixed in a separate container and added slowly to the vessel containing the resins under agitation. The defoamer and surfactant were then added and allowed to mix for 15 minutes under mild agitation. Next, the conductive spheres were slowly added with continued mild agitation, while allowing the spheres to wet out completely. The graphite was then added slowly under mild agitation, and the entire mixture continued to mix for 20 minutes under mild agitation.

Laboratory testing data obtained with the foregoing formulation on the liner according to the present invention, and using ASTM D 4935-99 as the measurement standard, showed shielding effectiveness greater than that demonstrated by a commercially available mobileCloak™ shielding product as summarized below. As specified in the ASTM standard that was used, shielding effectiveness (SE) is the ratio of power received with and without a material present for the same incident power and is usually expressed in decibels by the following equation:
SE=10 log(P₁/P₂)(decibels, dB)

where P₁ is equal to received power with the material present and P₂ is equal to the received without the material present. For the testing, which was conducted at DOW Chemical Corporation, the higher the dB attenuation, the better the shielding effectiveness. The PEMS product according to the present invention demonstrated an average improvement over the mCloak™ product of 9.4 dB over all tested frequencies, as follows:

| | PEMS Shielding | mCloak ™ Shielding |
|---|---|---|
| Frequency | Effectiveness | Effectiveness |
| in MHz | in dB | in dB |
| 30 | 55 | 52 |
| 100 | 69 | 61 |
| 200 | 77 | 67 |
| 300 | 63 | 62 |
| 400 | 73 | 61 |
| 500 | 67 | 62 |
| 600 | 68 | 61 |
| 700 | 64 | 56 |
| 800 | 71 | 57 |
| 900 | 69 | 56 |
| 1000 | 78 | 59 |
| 1100 | 78 | 61 |
| 1200 | 63 | 60 |
| 1300 | 62 | 59 |
| 1400 | 66 | 63 |
| 1500 | 67 | 59 |
| 1600 | 83 | 61 |
| 1700 | 62 | 58 |
| 1800 | 73 | 56 |
| 1900 | 66 | 59 |
| 2000 | 90 | 62 |

In an alternate coating composition, the preferred coating composition described above may be formulated but without the graphite particles. In this alternate coating composition, the microspheres provide the necessary attenuation characteristics. The coating thickness remains the same, about 0.001 to about 0.010 inches, with the preferred range again being 0.002 to 0.006 inches.

The exterior design of each model of the PEMS unit is attractive and yet non-descript so as not to be easily identified as a security device; instead they appear to be ordinary electronic cases. The exterior material 58 is preferably made of tight mesh material such as woven nylon; other suitable materials, whether woven or non-woven, may also be used. The PEMS units 10, 20, 30 are constructed so as to minimize seams, with the inner liner being sewn together so as to create contact with itself and not allow for an electromagnetic barrier breach across any seam. For example, two pieces of material to be joined are overlapped and then folded against one another and secured by sewing or other comparable fastening method. By this folded overlapping approach, tension on the seam does not cause gapping between the two pieces of fabric as may occur with regular seam construction. In addition, the flexibility of the coating composition, as already noted, allows the two-part barrier layer to be folded in this manner without damage, such as cracking, to the coating layer.

The PEMS units are easy to use and do not require special training or procedures to be used effectively. All that is necessary to ensure proper functioning is to place the appropriate electronic device into the body cavity 60 of the PEMS unit for which it is designed, snap the clasp to close the flap, and effective shielding operation of the PEMS unit is assured. The units are highly durable, the sensitive shielding materials being protected within the exterior outer fabric which is thick and padded, so as to afford shielding effectiveness for several years under normal conditions.

While certain representative embodiments and details have been shown for the purpose of illustrating the invention, it will be apparent to those skilled in this art that various changes, modifications and variations may be made therein without departing from the scope of the invention. Accordingly, it is intended to embrace all such changes, modifications and variations that fall within the spirit and scope of the appended claims. All patent applications, patents and other publications cited herein are incorporated by reference in their entirety. All parts and percentages are by weight unless otherwise explicitly stated.

1. A personal electromagnetic security (PEMS) unit for electromagnetically shielding a portable electronic device placed within an internal body cavity of said unit, comprising:
a two-part barrier layer including a metallized fabric substrate coated with an attenuating coating layer, said two-part barrier layer constituting an inner liner of said internal body cavity of said unit;
an exterior layer; and
a layer of padding material interposed between said inner liner and said exterior layer.

2. The PEMS unit as set forth in claim 1, wherein said coating layer is adjacent said padding layer, an uncoated side of said metallized fabric substrate interfacing with said internal body cavity.

3. The PEMS unit as set forth in claim 1, wherein said coating layer has a thickness of between about 0.001 and 0.01 inches.

4. The PEMS unit as set forth in claim 1, wherein said coating layer has a thickness of between about 0.002 and 0.006 inches.

5. The PEMS unit as set forth in claim 1, wherein said exterior layer is made of a tight mesh material.

6. The PEMS unit as set forth in claim 5, wherein said tight mesh material is woven nylon.

7. The PEMS unit as set forth in claim 1, wherein seams in said inner liner include an overlapped portion formed with two pieces of said liner that are then folded against one another and sewn to prevent an electromagnetic barrier breach across any seam.

8. The PEMS unit as set forth in claim 1, wherein said unit includes a flap that folds over an access opening to said internal body cavity, said flap being secured to said exterior layer with a clasp.

9. The PEMS unit as set forth in claim 1, wherein said coating layer includes by weight in parts per 100, 31.0 parts acrylic resin #1, 11.0 parts XHNBR latex #1, 12.5 parts water, 5.0 parts ethylene glycol monobutly ether, 1.0 parts defoamer #1, 1.0 parts surfactant, 32.0 parts conductive spheres and 5.5 parts graphite.

10. A personal electromagnetic security (PEMS) unit comprising:
a body defining an interior cavity into which an electronic device to be electromagnetically shielded is inserted, said body including a front panel and a rear panel;
an overlapping flap formed integrally with said rear panel and extending therefrom to fit down over said front panel;
a snap-in clasp securing said flap against said front panel and tensioning an interior lip thereof to achieve a complete electromagnetic seal of said interior cavity;
said front panel, said rear panel and said flap having an inner liner and an exterior layer, said inner liner having a two-part barrier layer construction including a metallized fabric substrate coated with an attenuating coating layer.

11. The PEMS unit as set forth in claim 10, further comprising a layer of padding material interposed between said inner liner and said exterior layer.

12. The PEMS unit as set forth in claim 11, wherein said coating layer is adjacent said padding layer, an uncoated side of said metallized fabric substrate interfacing with said interior cavity.

13. The PEMS unit as set forth in claim 10, wherein said coating layer has a thickness of between about 0.001 and 0.01 inches.

14. The PEMS unit as set forth in claim 10, wherein said coating layer has a thickness of between about 0.002 and 0.006 inches.

15. The PEMS unit as set forth in claim 10, wherein said exterior layer is made of a tight mesh material.

16. The PEMS unit as set forth in claim 15, wherein said tight mesh material is woven nylon.

17. The PEMS unit as set forth in claim 18, wherein seams in said inner liner include an overlapped portion formed with two pieces of said liner that are then folded against one another and sewn to prevent an electromagnetic barrier breach across any seam.

18. The PEMS unit as set forth in claim 10, wherein said coating layer includes by weight in parts per 100, 31.0 parts acrylic resin #1, 11.0 parts XHNBR latex #1, 12.5 parts water, 5.0 parts ethylene glycol monobutly ether, 1.0 parts defoamer #1, 1.0 parts surfactant, 32.0 parts conductive spheres and 5.5 parts graphite.

19. A method for fabricating a personal electromagnetic security (PEMS) unit for shielding an electronic device placed therein, said method comprising:
formulating an attenuating coating mixture consisting of acrylic resin, XHNBR latex, water, ethylene glycol monobutly ether, defoamer, surfactant, conductive spheres and graphite, said step of formulating including,
placing the acrylic resin in a mixing vessel and subjecting said resin to slow speed agitation;
adding the XHNBR latex to said mixing vessel at a slow rate and allowing said latex to mix with the acrylic resin for about 5 minutes;
premixing the water and glycol ether and adding said premixture to said mixing vessel containing the resin and latex under agitation;
adding the defoamer and surfactant to said mixing vessel and mixing for about 15 minutes under mild agitation;
adding the conductive spheres to said mixing vessel with continued mild agitation, while allowing the spheres to wet out completely; and
adding the graphite to said mixing vessel under mild agitation and continuing to mix all components of said attenuating coating mixture for about 20 minutes under mild agitation;
coating one side of a metallized fabric substrate with said attenuating coating mixture to form an attenuating coating layer thereon; and
using said coated metallized fabric substrate as an inner liner of said PEMS unit.

20. The method as set forth in claim 19, further comprising the step of layering said liner with a layer of padding and an exterior layer to form said PEMS unit, said coated side facing said padding.
